(19) United States
(12) Patent Application Publication
(10) Pub. No.: US 2019/0013203 A1
(43) Pub. Date: Jan. 10, 2019

(54) Low-Temperature Dopant Activation Process Using a Cap Layer, and MOS Devices Including the Cap Layer

(71) Applicants: Raghav SREENIVASAN, San Jose, CA (US); Aditi CHANDRA, Los Gatos, CA (US); Arvind KAMATH, Los Altos, CA (US)

(72) Inventors: Raghav SREENIVASAN, San Jose, CA (US); Aditi CHANDRA, Los Gatos, CA (US); Arvind KAMATH, Los Altos, CA (US)

(21) Appl. No.: 16/030,269

(22) Filed: Jul. 9, 2018

Related U.S. Application Data
(60) Provisional application No. 62/529,663, filed on Jul. 7, 2017.

(51) Int. Cl. H01L 21/228; H01L 21/02; H01L 21/8238; H01L 27/092

(52) U.S. Cl. CPC H01L 21/228; H01L 21/02532; H01L 21/0228; H01L 21/324; H01L 21/823814; H01L 21/02288; H01L 27/092; H01L 21/823864

(57) ABSTRACT

A method of making a MOS device, a MOS device containing an aluminum nitride layer, and a CMOS circuit are disclosed. The method includes depositing an aluminum nitride layer on a structure including a silicon layer, depositing a dopant ink on the structure, and diffusing the dopant through the aluminum nitride layer into the silicon layer. The structure also includes a gate oxide layer on the silicon layer and a gate on the gate oxide layer. The dopant ink includes a dopant and a solvent. The MOS device includes a silicon layer, a gate oxide layer on the silicon layer, a gate on the gate oxide layer, and an aluminum nitride layer on the gate. The silicon layer includes a dopant on opposite sides of the gate.

### CROSS REFERENCE TO RELATED APPLICATION(S)

This application claims the benefit of U.S. Provisional Patent Application No. 62/529,663, filed on Jul. 7, 2017, incorporated herein by reference as if fully set forth herein.

### FIELD OF THE INVENTION

The present invention relates to the field(s) of metal-oxide-semiconductor (MOS) devices and methods of making MOS devices, especially by thin film processing and/or printing.

### DISCUSSION OF THE BACKGROUND

FIGS. 1A-E show intermediates in a conventional method of forming a MOS device by thin film processing. Referring to FIG. 1A, a conductive gate 30 is on a gate oxide layer 20, formed on a semiconductor layer 10 on a substrate (not shown). The semiconductor layer 10 may comprise an organic semiconductor or an inorganic semiconductor, such as single-crystal or polycrystalline silicon. When the semiconductor layer 10 comprises polycrystalline silicon, it may be formed by deposition of an amorphous or partially polycrystalline silicon layer that is subsequently (re)crystallized (e.g., by furnace or laser crystallization). The gate oxide layer 20 generally comprises silicon dioxide and may be formed by blanket deposition and annealing (e.g., to densify it) or, when the semiconductor layer 10 comprises silicon, by thermal growth. The gate 30 may comprise doped polysilicon and/or a metal (e.g., aluminum or tungsten) or metal silicide (e.g., tungsten silicide, titanium silicide, cobalt silicide, etc.). The gate 30 is generally formed by blanket deposition of the conductive material(s) and photolithographic patterning.

FIG. 1B shows the intermediate MOS device of FIG. 1A further including a sidewall spacer 35 and a patterned gate oxide 25. The sidewall spacer 35 comprises one or more insulating materials such as silicon dioxide and/or silicon nitride, and is generally formed by blanket (e.g., conformal) deposition of the insulating material(s) on the gate 30 and the gate oxide layer 20, and anisotropic (e.g., directional) etching. Thus, the sidewall spacer 35 contacts all of the sidewalls of the gate 30 and completely surrounds the gate 30. The gate oxide layer 20 is patterned using the gate 30 and the spacer 35 as a mask (e.g., when the spacer 35 includes an exposed surface layer of silicon nitride) or by simple overetching (e.g., when both the spacer 35 and the gate oxide layer 20 comprise silicon dioxide). The dimensions of the spacer 35 and the gate oxide layer 20 in FIG. 1B are not necessarily to scale.

Referring now to FIG. 1C, to protect the underlying semiconductor layer 10 during the next step, a thin silicon dioxide layer 40 is conformally deposited onto the structure of FIG. 1B. Thereafter, as shown in FIG. 1D, a dopant layer 50 is printed or coated onto the structure of FIG. 1C. The dopant layer 50 may be formed by printing or coating an ink that includes a source of a conventional dopant, such as boron, phosphorous, arsenic or antimony, a solvent, and a vehicle such as a polymer. The dopant layer 50 is formed after removing the solvent from the ink (e.g., by drying at a relatively low temperature, such as 50-130° C.). The structure of FIG. 1D is then heated at a relatively high temperature (e.g., 500-1000° C.) to diffuse the dopant from the layer 50 through the silicon dioxide layer 40 and into the semiconductor layer 10. to form source/drain terminals 60 and 65, as shown in FIG. 1E. (In general, one of the source/drain terminals 60 and 65 is the source and one is the drain; which one is the source and which one is the drain depends on the direction of flow of electric carriers across the channel of the device.)

When MOS devices having a smaller threshold voltage or breakdown voltage are desired, the gate oxide layer 20 must be thinner than 350 Å. However, the process exemplified in FIGS. 1A-E is generally more difficult to manufacture when the gate oxide layer 20 has a thickness of about 50 Å or less. The dry etch process for patterning the gate 30 and the spacer 35 must be controlled to prevent either severe under- or over-etch of the device. In regions where the gate or spacer was either under- or over-etched, the devices were deemed to be non-functional (see, e.g., the left-hand plots in FIG. 12).

In addition, such devices can pose reliability concerns. In instances of gate overetch, gate oxide defects were unacceptably high. The across-sheet uniformity of the resistance of the devices also suffered and was unacceptably high.

Furthermore, at temperatures such as the dopant activation temperatures in the previous paragraph, certain atoms may diffuse or migrate from certain substrates (e.g., metal foils, such as stainless steel) into the semiconductor layer 10, or may have issues resulting from thermal stress. Thus, there is a need to reduce the thermal budget (e.g., a cumulative amount of heat to which a structure is exposed during processing) during this critical stage of making MOS devices.

This “Discussion of the Background” section is provided for background information only. The statements in this “Discussion of the Background” are not an admission that the subject matter disclosed in this “Discussion of the Background” section constitutes prior art to the present disclosure, and no part of this “Discussion of the Background” section may be used as an admission that any part of this application, including this “Discussion of the Background” section, constitutes prior art to the present disclosure.

### SUMMARY OF THE INVENTION

In one aspect, the present invention relates to a method of making a MOS device, comprising depositing an aluminum nitride layer on a structure comprising a silicon layer, a gate oxide layer on the silicon layer, and a gate on the gate oxide layer; depositing a dopant ink on the structure, the dopant ink comprising a dopant and a solvent; and diffusing the dopant through the aluminum nitride layer into the silicon layer. The aluminum nitride layer may have a thickness of from 20-200 Å, for example. The method may further comprise making the structure, forming a sidewall spacer on side surfaces of the gate, activating the dopant after diffusing the dopant into the silicon layer, and/or removing the aluminum nitride layer after diffusing the dopant into the silicon layer.

For example, making the structure may comprise forming the gate oxide layer on the silicon layer, and forming the gate on the gate oxide layer. In further embodiments, making the structure may also comprise forming the silicon layer on the substrate. In some further embodiments, forming the gate oxide layer may comprise depositing silicon dioxide or a silicon dioxide precursor on the silicon layer, and annealing the silicon dioxide or the silicon dioxide precursor. Alternatively, forming the gate oxide layer may comprise thermally oxidizing the silicon layer. In other or further embodiments, forming the gate may comprise printing a gate precursor material on the gate oxide layer, and annealing the gate precursor material. Alternatively, forming the gate may comprise blanket-depositing a gate material layer on the gate oxide layer, and patterning the gate material layer to form the gate.

In another example, forming the sidewall spacer may comprise depositing an insulating material on a top surface and the side surfaces of the gate, and anisotropically (e.g., directionally) etching the insulating material.

In various embodiments, the substrate may comprise a sheet or foil of a metal (e.g., a stainless steel, copper, or titanium foil), or a sheet, disc, wafer or film of a ceramic, a glass (e.g., a glass sheet, disc, or wafer), or a thermoplastic or thermoset polymer. The substrate may also be a combination or laminate of such materials, alone or with another material. For example, the combination or laminate substrate may comprise two or more thermoplastic polymers, a ceramic-coated metal foil, a thermoplastic polymer-coated paper, etc.

The dopant may be activated at a temperature of at least 50° C. below a minimum activation temperature of an identical device having a silicon oxide layer in place of the aluminum nitride layer under identical activation conditions, the silicon oxide layer having a thickness identical to that of the aluminum nitride layer. For example, the dopant may be activated at a temperature of 600-740° C.

The dopant ink may comprise the dopant or a dopant source, the solvent, and a polymer vehicle. The dopant source may comprise a compound and/or precursor of antimony, arsenic, phosphorous, boron, or gallium. The polymer vehicle may comprise, for example, an acrylic or methacrylic polymer (e.g., a polymer comprising one or more polyacrylates and/or polymethacrylates, such as a poly[C₁-C₁₀ linear and/or branched alkyl]acrylate and/or a poly[C₁-C₁₀ linear and/or branched alkyl]methacrylate). The solvent for the dopant ink may comprise a linear, branched and/or cyclic alkane, a linear, branched and/or cyclic alcohol, a linear, branched or cyclic mono- or polyether, an aliphatic, alicyclic or aromatic amine and/or an unsubstituted or substituted arene, although the invention is not limited thereto.

The silicon layer may be formed by a process comprising depositing a silicon-containing ink on the substrate. In one example, depositing the silicon-containing ink comprises blanket-depositing the silicon-containing ink on the substrate, curing and/or annealing one or more silicon-containing components in the silicon-containing ink, and patterning the cured and/or annealed silicon-containing components. In an alternative example, depositing the silicon-containing ink comprises printing the silicon-containing ink on the substrate in a pattern, and curing and/or annealing one or more silicon-containing components in the silicon-containing ink. In various embodiments, the silicon-containing ink comprises a silane and a solvent in which the silane is soluble. For example, the silane may have the formula SiₓH_{y}X_{z}, where x is from 3 to 1,000,000, X is a halogen atom, and y+z equals a number completing all bonding sites on the x silicon atoms not bound to another silicon atom. In some examples, the silane may comprise a cyclosilane in which x is from 5 to 8, y is 2x, and z is 0. Alternatively, the silane may comprise a linear, branched and/or cyclic silane in which x is from 10 to 10,000 and z may be 0, although z is not limited to zero in such linear, branched and/or cyclic silanes. The solvent may be selected from alkanes, cycloalkanes, fluoroalkanes, arenes, arenes substituted with one or more alkyl, alkoxy, halo, or haloalkyl substituents, siloxanes, and cyclosiloxanes, although the invention is not limited to these solvents.

In some embodiments, making the structure further comprises depositing a silicon dioxide layer on the aluminum nitride layer, in which case the method may comprise depositing the dopant ink onto the silicon dioxide layer. In such embodiments, the dopant ink or dopant source may comprise a compound and/or precursor of boron or gallium. The silicon dioxide layer may have a thickness of from 10-200 Å.

In further embodiments, the method makes CMOS devices (e.g., the method comprises making a plurality of PMOS devices and a plurality of NMOS devices). In such embodiments, depositing the dopant ink may comprise printing (1) a PMOS ink comprising (i) a compound and/or precursor of boron or gallium and (ii) a first solvent over structures corresponding to the PMOS devices and (2) an NMOS ink comprising (i) a compound and/or precursor of antimony, arsenic, or phosphorous and (ii) a second solvent over structures corresponding to the NMOS devices. Additionally or alternatively, the method may further comprise removing the silicon oxide layer (when present) after diffusing the boron or gallium dopant through the aluminum nitride layer into the silicon layer corresponding to the PMOS devices, and diffusing the antimony, arsenic, or phosphorous dopant through the aluminum nitride layer into the silicon layer corresponding to the NMOS devices.

In some embodiments of the method of making CMOS devices, the method may further comprise removing the aluminum nitride layer after removing the silicon dioxide layer, and forming a new aluminum nitride layer on at least the structures corresponding to the NMOS devices before printing the NMOS ink onto the new aluminum nitride layer. The method of forming CMOS devices may also further comprise removing the new aluminum nitride layer after diffusing the antimony, arsenic, or phosphorous dopant into the silicon layer corresponding to the NMOS devices.

In a further aspect, the present invention relates to a MOS device, comprising a silicon layer, a gate oxide layer on the silicon layer, a gate on the gate oxide layer, and an aluminum nitride layer on the gate. The silicon layer includes a dopant on opposite sides of the gate. The gate may comprise a printed gate or a photolithographically-patterned gate. The device may further comprise (i) a sidewall spacer on side surfaces of the gate and an upper surface of the gate oxide layer, and/or (ii) a substrate supporting the silicon layer. The silicon layer may comprise a photolithographically-patterned silicon island or a printed silicon island, and may be formed from a silicon-containing ink as described herein. The aluminum nitride layer may have a thickness of from 20-200 Å. The sidewall spacer may comprise an insulating material. The substrate may be as described for the present method.

A still further aspect of the present invention relates to a CMOS circuit, comprising a plurality of the present NMOS devices (i.e., having a p-type dopant) and a plurality of the present PMOS devices (i.e., having an n-type dopant). Thus, each of the NMOS devices comprises the gate oxide layer, the gate, the silicon layer with an antimony, arsenic, or phosphorous dopant on opposite sides of the gate, and the aluminum nitride layer, and each of the PMOS devices includes a separate silicon layer, a separate gate oxide layer on the separate silicon layer, a separate gate on the separate gate oxide layer, and the aluminum nitride layer on the separate gate. The separate silicon layer includes a boron or gallium dopant on opposite sides of the separate gate.

The present invention also enables a MOS device manufacturing flow in which the patterned gate oxide stays intact (suitable for gate oxide layers having a thickness of, e.g., 20 A-200 A) and is not exposed to undercut or overetching risks. The edge of the patterned gate oxide is protected by the present aluminum nitride layer. The AlN cap layer provides protection against wet etch chemistries such as HF which may be used in subsequent processing. In addition, one or more steps of the gate dry etch process may be eliminated. The present method results in a high quality and highly uniform gate oxide (e.g., for uniform threshold voltages and, for MOS capacitors, breakdown voltages).

Furthermore, the dopant activation temperature and the pad oxide anneal temperature can be reduced (e.g., by 50-100° C. or more), which allows for reduced thermal stress. Dopant activation in silicon at temperatures as low as 650° C. can provide an active layer sheet resistance of 400 Ohms/sq, and at more conventional temperatures (e.g., 790° C.), active layer sheet resistances below 200 Ohms/sq can be achieved in what are otherwise identical devices.

The manufacturing process can be simplified, in that one or more gate dry etch process steps, spacer and spacer etch process steps, and other associated process steps can be eliminated.

### BRIEF DESCRIPTION OF THE DRAWINGS

FIGS. 1A-E show intermediates in a conventional process for making MOS devices by thin-film processing.

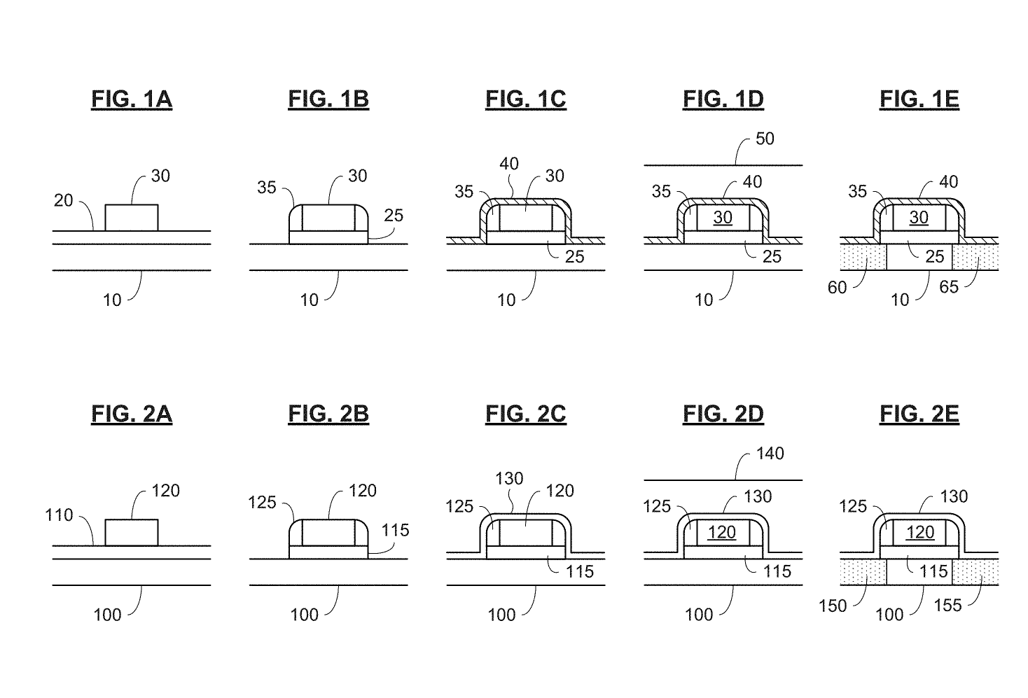

FIGS. 2A-E show exemplary intermediates in a process for making MOS devices in accordance with one or more embodiments of the present invention.

FIGS. 3A-H show exemplary intermediates in a process for making CMOS devices in accordance with one or more embodiments of the present invention.

FIGS. 4A-D show exemplary intermediates in an alternative process for making CMOS devices in accordance with one or more embodiments of the present invention.

FIGS. 5A-C show exemplary intermediates in a further alternative process for making CMOS devices in accordance with one or more embodiments of the present invention.

FIGS. 6A-B show exemplary integrated circuit architectures that can be made using CMOS devices produced in accordance with one or more embodiments of the present invention.

FIG. 7 shows an exemplary alternative integrated circuit architecture that can be made using CMOS devices produced in accordance with one or more embodiments of the present invention.

FIGS. 8A-B are flow charts for exemplary methods of making CMOS devices in accordance with embodiments of the present invention.

FIG. 9 is a graph comparing the breakdown voltage of NMOS devices made by an exemplary process according to the present invention with otherwise identical or substantially identical NMOS devices produced by a method representative of conventional processing.

FIG. 10 is a graph showing sheet resistances of NMOS devices annealed at different temperatures in accordance with embodiments of the present invention.

FIG. 11 is a graph comparing the sheet resistances of NMOS devices made by exemplary processes according to the present invention with otherwise identical or substantially identical NMOS devices produced by methods representative of conventional processing.

FIG. 12 shows plots comparing the capacitances of NMOS capacitors made by an exemplary process according to the present invention with otherwise identical or substantially identical NMOS capacitors produced by a method representative of conventional processing.

FIG. 13 is a variability chart showing the sheet resistance of a doped silicon layer prepared in accordance with an embodiment of the present method.

### DETAILED DESCRIPTION

Reference will now be made in detail to various embodiments of the invention, examples of which are illustrated in the accompanying drawings. While the invention will be described in conjunction with the following embodiments, it will be understood that the descriptions are not intended to limit the invention to these embodiments. On the contrary, the invention is intended to cover alternatives, modifications and equivalents that may be included within the spirit and scope of the invention. Furthermore, in the following detailed description, numerous specific details are set forth in order to provide a thorough understanding of the present invention. However, it will be readily apparent to one skilled in the art that the present invention may be practiced without these specific details. In other instances, well-known methods, procedures and components have not been described in detail so as not to unnecessarily obscure aspects of the present invention. Furthermore, it should be understood that the possible permutations and combinations described herein are not meant to limit the invention. Specifically, variations that are not inconsistent may be mixed and matched as desired.

For the sake of convenience and simplicity, and unless indicated otherwise from the context of its use herein, the terms “part,” “portion,” and “region” are, in general, interchangeable and may be used interchangeably herein, but are generally given their art-recognized meanings. Wherever one such term is used, it also encompasses the other terms. Similarly, for convenience and simplicity, and unless indicated otherwise from the context of its use herein, the terms “connected to,” “coupled to,” and “in communication with” (and grammatical variations thereof) may be used interchangeably herein, but are generally given their art-recognized meanings, and wherever one such term is used, it also encompasses the other terms. Also, unless indicated otherwise from the context of its use herein, the terms “known,” “fixed,” “given,” “certain” and “predetermined” generally refer to a value, quantity, parameter, constraint, condition, state, process, procedure, method, practice, or combination thereof that is, in theory, variable, but is typically set in advance and not varied thereafter when in use.

Exemplary Processes for Making MOS Devices

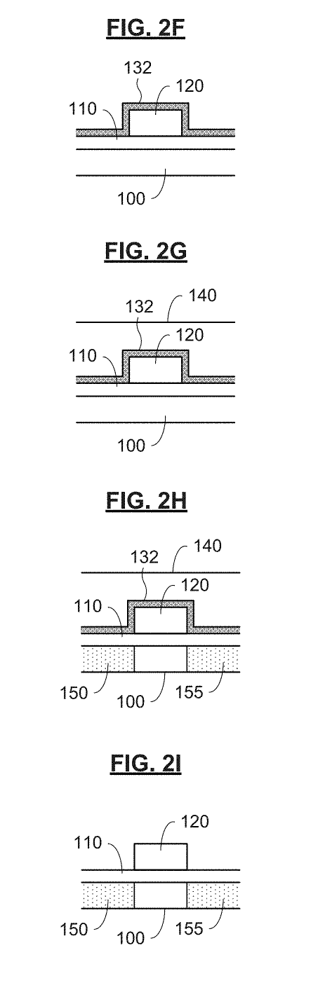

FIGS. 2A-E show exemplary intermediates in a first process for making MOS devices in accordance with one or more embodiments of the present invention. FIG. 2A shows a structure comprising a silicon layer 100, a gate oxide layer 110 on the silicon layer 100, and a gate 120 on the gate oxide layer 110. The silicon layer 100 may be on a substrate (not shown). The substrate may be or comprise a sheet or foil of a metal (e.g., a stainless steel, copper, aluminum, or titanium foil), or a sheet, disc, wafer or film of a ceramic, a glass (e.g., a glass sheet, disc, or wafer), or a polymer. When the substrate comprises a stainless steel or other metal substrate, the metal substrate may further include one or more diffusion barrier layers (e.g., comprising a layer of TiN, TaN, AlN, etc.) and/or one or more pad oxide (e.g., SiO₂) layers. When the metal substrate includes the diffusion barrier layer, the diffusion barrier layer may have a thickness of 300-2000 Å, and when the metal substrate includes the pad oxide layer, the pad oxide layer may have a thickness of 200 Å-2 μm.

The silicon layer 100 may comprise amorphous, microcrystalline, polycrystalline or single-crystal silicon. The silicon layer 100 may be formed by deposition of an amorphous or polycrystalline silicon layer (e.g., by plasma-aided chemical vapor deposition or low pressure chemical vapor deposition from a silane gas) that is subsequently crystallized (e.g., by furnace anneal or laser crystallization). Alternatively, the silicon layer may be formed by depositing a silicon-containing ink on the substrate. The silicon-containing ink may be deposited by blanket-depositing the silicon-containing ink on the substrate, curing and/or annealing one or more silicon-containing components in the silicon-containing ink, and patterning the cured and/or annealed silicon-containing components. Alternatively, the silicon-containing ink may be deposited by printing the silicon-containing ink on the substrate in a pattern, and curing and/or annealing one or more silicon-containing components in the silicon-containing ink.

The silicon-containing ink may comprise a source of elemental silicon (as the silicon-containing component[s]) and a solvent. The source of elemental silicon may be or comprise silicon nanoparticles and/or a silane. The silane may have the formula SiₓH_{y}X_{z}, where x is from 3 to 1,000,000, and y+z is a number completing all bonding sites on the x silicon atoms not bound to another silicon atom. For example, the silane may comprise a cyclosilane, in which x is from 5 to 8, y is 2x, and z is 0 in the above formula. Alternatively or additionally, the silane may be or comprise a linear, branched and/or cyclic silane, where x is from 10 to 10,000. In some embodiments, z is less than x/n, where n is an integer of at least one, but not greater than x. For example, z may be 0.

The solvent may be one in which the silicon nanoparticles (when present) are soluble or suspendable and the silane (when present) is soluble. For example, the solvent may be selected from alkanes, cycloalkanes, fluoroalkanes, arenes, substituted arenes, siloxanes, and cyclosiloxanes. The substituted arenes may include one or more alkyl, alkoxy, halo, or haloalkyl substituents. For example, the solvent may include a C₆-C₁₂ alkane, a C₆-C₁₂ mono-, di- or polycycloalkane, benzene, toluene, one or more xylenes, or cyclo-(OSiMe₂)ₐ, where a in an integer of from 3 to 6.

The gate oxide layer 110 generally comprises silicon dioxide. In some embodiments, the gate oxide layer 110 may be formed by blanket deposition and annealing. For example, the blanket deposition may include plasma-aided chemical vapor deposition from a silicon dioxide precursor such as tetraethyl orthosilicate (TEOS) or a combination of silane gas and N₂O or oxygen. The blanket-deposited silicon dioxide layer may be subsequently annealed (e.g., at a temperature of 300-1000° C.) to densify it. Alternatively, the gate oxide layer 110 may be formed by conventional thermal growth (e.g., heating in a furnace or rapid thermal annealing oven at a temperature of 900-1050° C.).

The gate 120 may comprise doped polysilicon and/or a metal. The polysilicon may be heavily doped with one or more dopants such as boron, gallium, phosphorous, arsenic and antimony. The metal may be or comprise aluminum, tungsten, molybdenum, or an alloy thereof. The gate may comprise a metal nitride (TiN, WN, etc.). The gate 120 may also comprise a metal silicide such as tungsten silicide, titanium silicide, cobalt silicide, etc. The gate 120 is generally formed by blanket deposition of the conductive material(s), optional annealing if the gate 120 comprises polysilicon or a metal silicide, and photolithographic patterning. The gate material may be blanket deposited to a thickness of 300-5000 Å, or any thickness or range of thicknesses therein, then etched (with a patterned hard mask thereon) by dry or wet etching to form the gate layer 120. Wet etching may be advantageous due to an increase in etching selectivity. For example, an aqueous solution of NH₄OH and H₂O₂ can be used to wet etch a metal (e.g., tungsten) layer, and TMAH (tetramethyl ammonium hydroxide) can be used to wet etch a polysilicon layer, to form the gate layer 120.

FIG. 2B shows the intermediate MOS device of FIG. 2A further including a sidewall spacer 125 and a patterned gate oxide 115. The sidewall spacer 125 comprises one or more insulating materials such as silicon dioxide and/or silicon nitride, and is generally formed by blanket (e.g., conformal) deposition of the insulating material(s) on the gate 120 and the gate oxide layer 110, and isotropic (e.g., directional) etching. Thus, the sidewall spacer 125 contacts all of the sidewalls of the gate 120 and completely surrounds the gate 120. The patterned gate oxide layer 115 may be formed by etching (e.g., dry, plasma-aided etching) using the gate 120 and the spacer 125 as a mask (e.g., when the spacer 125 includes an exposed surface layer of silicon nitride). When both the spacer 125 and the gate oxide layer 110 comprise silicon dioxide, the patterned gate oxide layer 115 may be formed by simple overetching. The dimensions of the spacer 125 and the gate oxide layer 110 in FIG. 2B are not necessarily to scale.

Referring now to FIG. 2C, to protect the underlying spacer 125, gate oxide 110 and silicon layer 100 during subsequent processing, a thin aluminum nitride layer 130 is conformally deposited onto the structure of FIG. 2B. Alternatively, the aluminum nitride can be replaced by an oxide or oxynitride of aluminum that may further contain silicon, such as Al₂O₃, an aluminum oxynitride, an aluminosilicate, etc. (e.g., a material of the formula AlₓSi_{y}NₚO_{q}, where x>0, x≥y/9 [e.g., x≥y], and 4p+3q=4x+6y). In various embodiments, y=0, p>0, and/or q=0.

Alternatively, the aluminum nitride can be replaced by a bilayer of AlₓN/SiO₂, Al₂O₃/SiO₂, SiO₂/AlN, SiO₂/Al₂O₃ or a combination thereof. The bilayer can be formed during the same deposition step or process, or may be formed in separate processes. The deposition may be done by ALD, CVD, LPCVD, PECVD, or a combination thereof, as described herein. Additionally, the insulating layer(s) (e.g., SiO₂) may be printed or coated using an ink (e.g., a polysilazane). Printing may include extrusion coating, micro gravure printing, etc. Alternatively, the insulating layer(s) may be formed at least in part by spin coating an ink containing the insulator or a precursor thereof.

The aluminum nitride layer 130 may be formed by chemical vapor deposition (CVD, which may be plasma-assisted or -enhanced) using an aluminum source such as a trialkylaluminum (e.g., a C₁-C₆ trialkylaluminum, such as trimethylaluminum, triethylaluminum, triisobutylaluminum, etc.) and a nitrogen source such as ammonia or hydrazine, or a source of both aluminum and nitrogen such as tris(dimethylamido)aluminum or tris(diethylamido)aluminum. Alternatively, the aluminum nitride layer 130 may be formed by atomic layer deposition (ALD) using the same materials as used in CVD. In a further alternative, the aluminum nitride layer 130 may be formed by physical vapor deposition (which may be plasma-assisted or -enhanced) or sputtering using an aluminum source such aluminum metal and a nitrogen source such as ammonia or dinitrogen. The AlN layer 130 may have a thickness of from 20-200 Å (e.g., 30-100 Å, or any value or range of values within the range of 20-200 Å). Other materials that may be used may be formed similarly to aluminum nitride, from known reagents and/or source materials, and may have a thickness within the range(s) mentioned for the aluminum nitride layer 130.

Thereafter, as shown in FIG. 2D, a dopant layer 140 is printed or coated onto the structure of FIG. 2C. The dopant layer 140 may be formed by printing or coating an ink that includes a source of a conventional dopant, such as boron, gallium, phosphorous, arsenic or antimony, a solvent, and a vehicle such as a polymer that can be subsequently removed (e.g., by conventional ashing). The dopant source may comprise an elemental dopant (e.g., red phosphorous, white phosphorous, etc.), a perhydro dopant (e.g., a borane such as diborane, tetraborane, decaborane, etc.; phosphine [PH₃], arsine {AsH₃], or stibine [SbH₃]), a dopant oxide (e.g., boron oxide [B₂O₃], phosphorous pentoxide [P₂O₅], phosphoric acid [H₃PO₄] or an ester thereof, a boron- or phosphorous-doped glass, etc.), or a compound of the formula DₐR¹_{b}, where D is antimony, arsenic, phosphorous, boron or gallium, a is from 1 to 20 (e.g., 1 or 2), and b is from 0 to 26 (e.g., 3a). In such formulations, each of the b instances of R¹ may be independently H, alkyl (e.g., C₁-C₆ alkyl), aryl (e.g., C₆-C₁₀ aryl), aralkyl (e.g., C₇-C₁₀ aralkyl), a halogen (e.g., F, Cl, Br, or I), O, OR² or NR²₂, where R² is H or C₁-C₄ alkyl. The dopant source may be present in an amount of from about 0.1 wt. % to 10 wt. % of the ink, or any value or range of values therein (e.g., from about 0.2 wt. % to 2 wt. %, 0.3 wt. % to 1 wt. %, etc.).

The solvent may be any solvent or solvent combination with which the polymer vehicle(s) and/or the dopant(s) can be mixed and/or in which the polymer vehicle(s) and/or the dopant(s) are soluble. Solvents suitable for use with embodiments of the present invention may comprise a linear, branched, and/or cyclic alkane, a linear, branched and/or cyclic alcohol, a linear, branched, or cyclic mono- or polyether, an aliphatic, alicyclic, or aromatic amine, ketones, and/or an unsubstituted or substituted aromatic. For example, the one or more solvents in the dopant formulation may comprise a C₁-C₂₀ linear, branched and/or cyclic saturated or unsaturated alcohol (e.g., ethanol, isopropanol, α-terpineol, etc.). Other suitable solvents may include a C₆-C₁₂ unsubstituted or substituted arene (e.g., toluene, xylene[s], etc.), a C₅-C₁₂ linear and/or branched alkane, a C₆-C₁₂ monocycloalkane, an aliphatic ether such as a di-C₂-C₆ alkyl ether, a methyl C₄-C₆ alkyl ether, or a di-C₁-C₄ alkyl C₂-C₆ alkylene diether [e.g., glyme], a cyclic ether [e.g., tetrahydrofuran, dioxane, etc.], a mono-, di- or tri-C₁-C₁₀ linear and/or branched amine, or a mono- or polycyclic aromatic amine [e.g., pyridine, quinoline, etc. In exemplary embodiments, the solvent comprises terpineol or a solvent mixture including terpineol. All forms of terpineol may be used. The dopant ink may comprise a single solvent or a mixture of first and second solvents. The first and/or second solvents may comprise any of the solvents described herein. For example, one solvent may comprise a C₃-C₂₀ linear, branched and/or cyclic, saturated or unsaturated alcohol, and optionally, another solvent in the solvent mixture may comprise a C₆-C₁₂ unsubstituted or substituted arene. The first and second solvents may be present in a ratio of from about 1:10 to 10:1, or any value or range of values therein. The solvent(s) may be present in the formulation in an amount of from about 1 wt. % to 90 wt. % of the ink, or any value or range of values therein (e.g., from about 20 wt. % to 80 wt. %, 30 wt. % to 70 wt. %, etc.).

The vehicle(s) may comprise or consist essentially of an organic polymer, such as an acrylic-, methacrylic-, or ethyl cellulose-based resin. In general, when the dopant ink with an organic polymer vehicle is deposited on a substrate and is subsequently cured, the organic polymer decomposes to leave essentially no or only a trace amount of carbon-containing residue. Although acrylic-, methacrylic-based, or ethyl cellulose-based resins are preferred polymer vehicles, the invention is not limited as such, and other polymers may be employed. A large variety of suitable polymer vehicles are widely commercially available with respect to the type of resin, its molecular weight or molecular weight range (e.g., weight-average and/or number-average molecular weight), glass transition temperature (Tg), acid value, viscosity, and solubility characteristics.

In one embodiment, the vehicle includes an acrylic polymer comprising one or more polyacrylates and/or polymethacrylates. For example, in some variations, the acrylic polymer may comprise a poly(C₁-C₁₀ linear and/or branched alkyl)acrylate and/or a poly(C₁-C₁₀ linear and/or branched alkyl)methacrylate. In various embodiments, the acrylic polymer can be an acrylic homopolymer, an acrylic copolymer, and/or a blend of acrylic polymers. If the acrylic polymer is a copolymer, it may be a copolymer of two or more (meth)acrylate monomers, and the copolymer may be either a random copolymer or a block copolymer. In one exemplary embodiment, the poly(C₁-C₁₀ linear and/or branched alkyl)methacrylate comprises poly(isobutyl)methacrylate. In exemplary embodiments, the polymer vehicle(s) are present in the ink in an amount of from about 1 wt. % to 60 wt. %, or any other value or range of values therein (e.g., from about 5 wt. % to 60 wt. %, about 10 wt. % to 40 wt. %, etc.).

The dopant layer 140 is formed after removing the solvent from the ink (e.g., by drying at a relatively low temperature, such as 50-130° C.). The structure of FIG. 2D is then heated at a relatively high temperature (e.g., 500-1000° C.) to diffuse the dopant from the layer 140 through the aluminum nitride layer 130 and into the silicon layer 100. This forms the source/drain terminals 150 and 155, as shown in FIG. 2E. (In general, one of the source/drain terminals 150 and 155 is the source and one is the drain; which one is the source and which one is the drain depends on the direction of flow of electric carriers across the channel of the device.) Prior to the dopant activation anneal, the pad oxide layer on the substrate is annealed at a higher temperature. Typically, in the absence of the aluminum nitride layer 130 (FIG. 2C), the pad oxide is annealed at a temperature of 800-1000° C. (e.g., 850-900° C.). However, with the use of AlN, the dopant anneal temperature may be reduced, which lowers the temperature for the pad oxide anneal. (e.g. 700-830° C.). Thus, there may be a reduction of 20-200° C. in the pad oxide annealing temperature. The reduced dopant activation temperature also reduces the diffusion of metal atoms from the metal substrate through the diffusion barrier and/or pad oxide layers. In any case, the substrate must be capable of mechanically withstanding the dopant activation conditions (e.g., a temperature of 650-800° C. for a length of time generally of at least 5 minutes). In subsequent processing, the surface may undergo a surface cleaning step comprising a combination of dry and wet etch steps (e.g., treatment with an oxygen plasma, steam cleaning, an HF etch, cleaning with SCl solution, etc.). The AlN layer may stay intact, or may be wet or dry etched before the next step.

The method may further comprise conventional blanket deposition (e.g., by spin coating, depositing by CVD [which may be plasma-aided], etc.) of an interlayer dielectric on the structure in FIG. 2E, followed by via or contact hole formation (e.g., by patterning and etching) and metal interconnect formation (e.g., by printing or by blanket deposition and patterning). Alternatively, the interlayer dielectric may be printed in a pattern exposing parts of the source/drain terminals 150 and 155, and the metal interconnect may be formed by first printing an ink comprising a metal capable of forming (i) a metal silicide contact onto the exposed parts of the source/drain terminals 150 and 155 and/or (ii) a seed layer for a bulk metal interconnect onto the interlayer dielectric, and the bulk metal for the bulk metal interconnect may be plated (e.g., by electroplating or electroless plating) onto the seed layer.

The dopant from the dopant layer 140 may be activated at a temperature of at least 50° C. below a minimum activation temperature of an identical device having a silicon dioxide layer in place of the aluminum nitride layer 130 under identical activation conditions, the silicon dioxide layer having a thickness identical to that of the aluminum nitride layer 130. For example, when the dopant is an NMOS dopant that is activated at a temperature of 790° C. in a device having a silicon dioxide layer in place of the aluminum nitride layer 130, the dopant in the device having an aluminum nitride layer 130 may be activated at a temperature of 650-740° C. Under different conditions, and/or using a different dopant and/or semiconductor layer, the activation temperature can be further reduced to 600° C. or less. In turn, the reduction in the annealing temperature enables a reduction of the annealing temperature of any pad oxide that may be present, further enabling a reduction in or elimination of thermal stress cracking.

The present method can also simplify the manufacturing process flow and reduce or limit the use of dry etch and plasma-enhanced chemical vapor deposition (PECVD) tools (e.g., by eliminating gate dry etching and gate ashing steps, and in some cases, the spacer deposition, spacer etching and spacer ashing steps). For example, when the process forms MOS devices of a single type (e.g., NMOS devices) having a thin gate oxide layer (e.g. 20-200 A), it is not necessary to etch the gate oxide layer 110 prior to deposition of the aluminum nitride layer 130. Furthermore, it may not be necessary to include the sidewall spacer 125 at all (e.g., when the dopant diffusion pattern and/or the gate dimensions enable one to avoid use of the sidewall spacer 125). For example, FIG. 2F shows the structure of FIG. 2A with a thin aluminum nitride layer 132 thereon. The dopant layer 140 is formed on the aluminum nitride layer 132, as described herein and shown in FIG. 2G. The dopant from the layer 140 is diffused through the aluminum nitride layer 132 and into the silicon layer 100 to form source/drain terminals 150 and 155, as described herein and shown in FIG. 2H. Removal of the layer 140 and the aluminum nitride layer 132 as described herein leaves the MOS device, as shown in FIG. 21.

The present process also significantly reduces the active sheet resistance of the devices, enabling a high Q for integrated circuits and wireless circuits that detect and/or process a wireless signal, such as a radio frequency (RF), high frequency (HF), very high frequency (VHF), ultra-high frequency (UHF), or near field communication (NFC) signal.

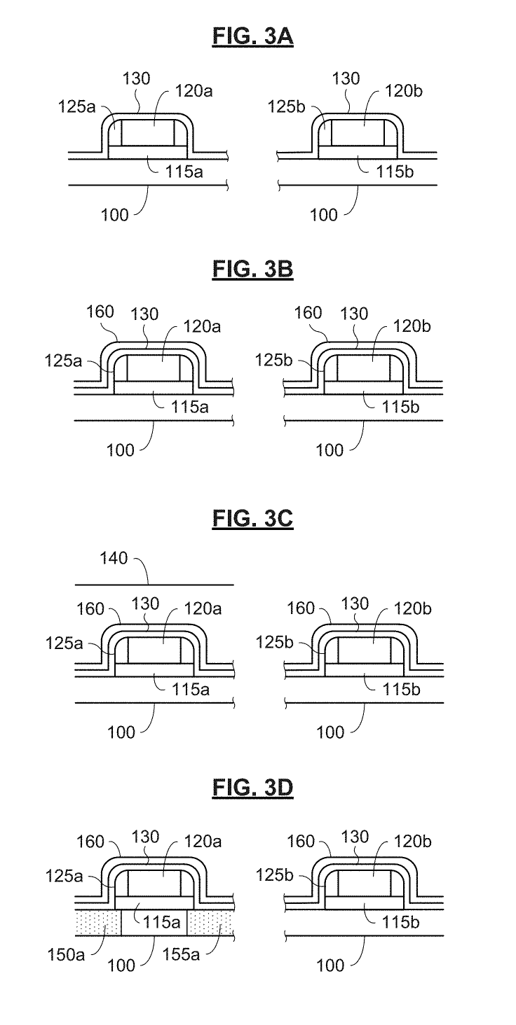

FIGS. 3A-H show exemplary intermediates in a process for making CMOS devices in accordance with one or more embodiments of the present invention. FIG. 3A shows two structures similar or identical to the structure shown in FIG. 2C, including a silicon layer 100, patterned gate oxides 115a-b, gates 120a-b, sidewall spacers 125a-b and a thin aluminum nitride layer 130. The structures in FIG. 3A may be made similarly or identically to the structure shown in FIG. 2C. One of the structures in FIG. 3A will become a PMOS device and the other will become an NMOS device.

As is shown in FIG. 3B, a thin silicon dioxide layer 160 is formed over the aluminum nitride layer 130, generally by blanket and/or conformal deposition. For example, the silicon dioxide layer 160 may be formed by plasma-aided chemical vapor deposition from a silicon dioxide precursor such as tetraethyl orthosilicate (TEOS) or a combination of silane gas and oxygen. The silicon dioxide layer 160 may be annealed (e.g., at a temperature of 300-450° C.) to densify it and/or to remove any organic residues or components. The silicon dioxide layer 160 may have a thickness of 10-100 Å, or any value or range of values therein.

A first dopant layer 140 is formed over the left-hand structure, as shown in FIG. 3C. The first dopant layer 140 may be formed by printing a first dopant ink over the structures that will become PMOS devices, for example. In such a case, the first dopant ink may comprise a source of boron or gallium, a solvent, and a carrier, as described above. The dopant layer 140 is formed after removing the solvent from the ink (e.g., by drying at a relatively low temperature, such as 50-130° C.). Alternatively, the first dopant layer 140 may be formed over the entire substrate and all of the gates, and the portion of the dopant layer 140 over the structures corresponding to NMOS devices can be removed.

The structure of FIG. 3C is then heated at a relatively high temperature (e.g., 500-1000° C.) to diffuse the dopant from the layer 140 through the silicon dioxide layer 160 and the aluminum nitride layer 130 and into the silicon layer 100 to form source/drain terminals 150a and 155a, as shown in FIG. 3D.

In the exemplary process of FIGS. 3A-H, the silicon dioxide layer 160 and the aluminum nitride layer 130 are removed (see FIG. 3E), and as shown in FIG. 3F, a new (or second) aluminum nitride layer 135 is formed over the structure of FIG. 3E. The silicon dioxide layer 160 may be removed by wet or dry etching (e.g., selective to the underlying aluminum nitride layer 130) using a first etchant, and the underlying aluminum nitride layer 130 may be removed by wet or dry etching (e.g., selective to the underlying gates 120a-b, sidewall spacers 125a-b, and silicon layer 100) using a second etchant. It is within the level of skill of those skilled in the art to determine empirically specific etchants and etching conditions for removing the silicon dioxide layer 160 and the aluminum nitride layer 130. Optionally, the same AlN layer may be used in the processes for formation of both NMOS and PMOS devices without the need for removing the AlN layer between the two processes.

As is shown in FIG. 3G, a second dopant layer 170 is formed over the right-hand structure (i.e., without source/drain terminals 150a and 155a). The second dopant layer 170 may be formed by printing a second dopant ink over the structures that will become NMOS devices, for example. In such a case, the second dopant ink may comprise a source of phosphorous, arsenic or antimony, a solvent, and a carrier, as described above. The second dopant layer 170 is formed after removing the solvent from the ink (e.g., by drying at a relatively low temperature, such as 50-130° C.). The structure of FIG. 3G is then heated at a relatively high temperature (e.g., 500-1000° C.) to diffuse the dopant from the layer 170 through the second aluminum nitride layer 135 and into the silicon layer 100 to form source/drain terminals 150b and 155b, as shown in FIG. 3H.

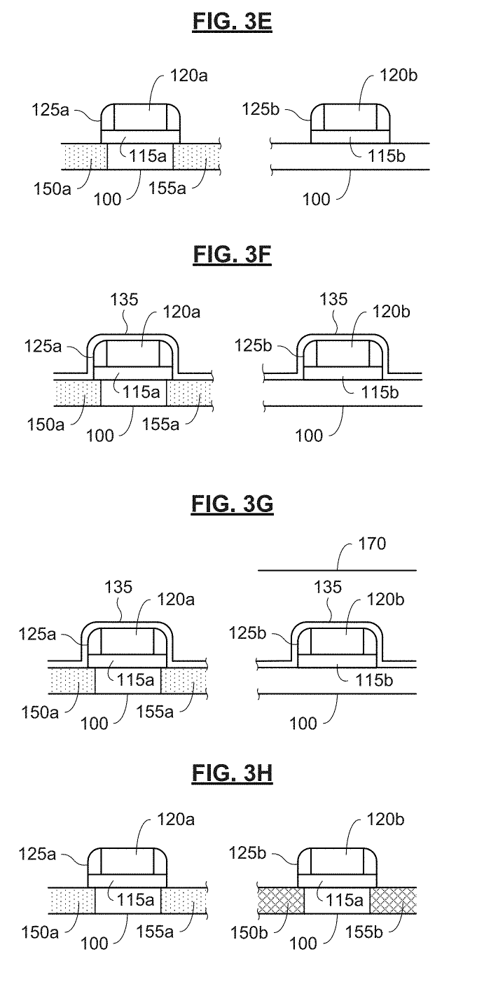

FIGS. 4A-D show exemplary intermediates in an alternative process for making CMOS devices in accordance with one or more embodiments of the present invention. FIG. 4A shows two structures similar to the structures shown in FIG. 3D, including a silicon layer 100, patterned gate oxides 115a-b, gates 120a-b, sidewall spacers 125a-b, a thin aluminum nitride layer 130 and first source/drain terminals 150a and 155a, but without the silicon dioxide layer 160. The structures in FIG. 4A may be made similarly or identically to the structures shown in FIG. 3E, but the first aluminum nitride layer 130 is not removed. The left-hand structure in FIG. 4A is a PMOS device or an NMOS device, and the right-hand structure in FIG. 4A will become the other device. In one example, the left-hand structure in FIG. 4A is a PMOS device and the right-hand structure is an NMOS device, but the invention is not so limited.

FIG. 4B shows the second dopant layer 170 formed over the structure in which source/drain terminals have not yet been formed. The second dopant layer 170 in FIG. 4B may be formed in a similar or identical manner as the second dopant layer 170 in FIG. 3G. After heating at a relatively high temperature (e.g., 500-1000° C.) to diffuse the dopant from the layer 170 through the aluminum nitride layer 130 and into the silicon layer 100, source/drain terminals 150b and 155b are formed, as shown in FIG. 4C.

As is shown in FIG. 4D, the aluminum nitride layer 130 may be removed by wet or dry etching (e.g., using an etchant that is selective for etching aluminum nitride relative to the underlying gates 120a-b, sidewall spacers 125a-b, and silicon layer 100), either before or after activating the dopant from the second dopant layer 170. In one example, the aluminum nitride layer 130 is removed after activating the second dopant to form source/drain terminals 150b and 155b, but the invention is not so limited. For example, the aluminum nitride layer 130 may be retained (i.e., not etched) after dopant activation, as shown in FIG. 4C. In such a case, the aluminum nitride layer 130 may function as an etch stop layer during the process for making gate, source and drain contacts.

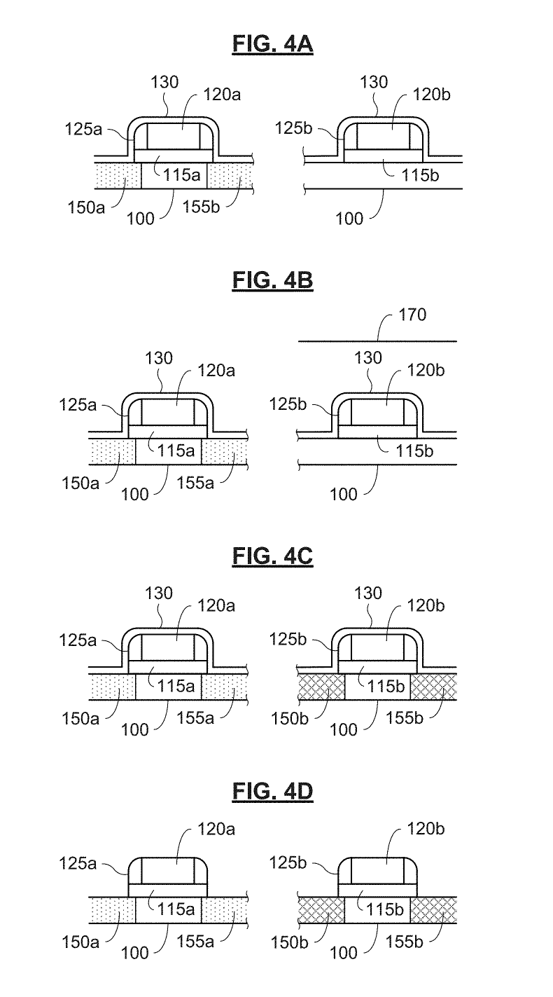

FIGS. 5A-C show exemplary intermediates in a further alternative process for making CMOS devices in accordance with one or more embodiments of the present invention. FIG. 5A shows two structures similar to the structures shown in FIG. 3B, including a silicon layer 100, patterned gate oxides 115a-b, gates 120a-b, sidewall spacers 125a-b, the thin aluminum nitride layer 130, and the silicon dioxide layer 160. However, the silicon dioxide layer 160 is over only the left-hand structure (e.g., the structure that will become the PMOS device). The structures in FIG. 5A may be made similarly or identically to the structures shown in FIG. 3B, but the silicon dioxide layer 160 is removed from the right-hand structure (e.g., by masking the structures that will become PMOS devices, selectively etching the silicon dioxide layer 160 over the structures that will become NMOS devices, and removing the mask from over the structures that will become the PMOS devices).

FIG. 5B shows a first dopant layer 140 over the left-hand structure and second dopant layer 170 formed over the right-hand structure. Source/drain terminals have not yet been formed in either device. The first dopant layer 140 may be formed by printing a first dopant ink over the structures that will become PMOS devices, for example, and the second dopant layer 170 may be formed by separately printing a second dopant ink over the structures that will become NMOS devices. In such a case, the first dopant ink may comprise a source of boron or gallium, a solvent, and a carrier, and the second dopant ink may comprise a source of phosphorous, arsenic or antimony, a solvent, and a carrier, as described above. The solvent and the carrier in the second dopant ink may be independently the same as or different from the solvent and the carrier in the first dopant ink. The dopant layers 140 and 170 are formed after removing the solvent from the respective inks (e.g., by drying at a relatively low temperature, such as 50-130° C.).

Heating at a relatively high temperature (e.g., 500-1000° C.) diffuses the dopants from (i) the first dopant layer 140 through the silicon dioxide layer 160 and the aluminum nitride layer 130 and (ii) the second dopant layer 170 through the aluminum nitride layer 130 into the silicon layer 100, to form source/drain terminals 150a-b and 155-b, as shown in FIG. 5C.

Exemplary Integrated Circuits including the Present CMOS Devices

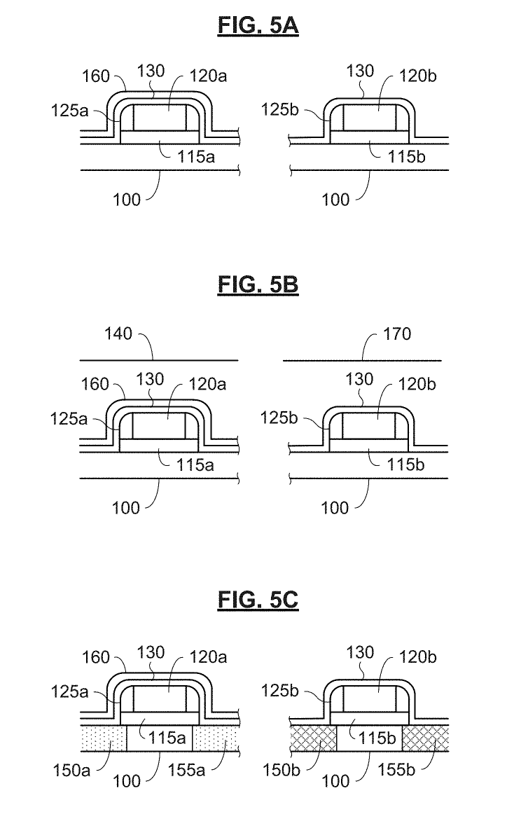

FIGS. 6A-B show exemplary integrated circuit architectures that can be made using CMOS devices produced in accordance with one or more embodiments of the present invention. FIG. 6A shows an exemplary resonant circuit 200 for an electronic article surveillance (EAS) tag. Generally, the EAS tag 200 includes an inductor (e.g., an inductor coil) 210 and a capacitor 220. The capacitor 220 may comprise an NMOS or PMOS device manufactured as described herein and in which the source/drain terminals are electrically connected, as is known in the art. The capacitor 220 may be linear (as shown) or non-linear, in which case the gate may include a semiconductor layer and a metal or metal silicide layer on or in contact with the semiconductor layer. In the presence of an oscillating wireless signal (or electromagnetic field), the inductor 210 is configured to generate or produce a current in the resonant circuit 200 sufficient for the tag to backscatter detectable electromagnetic (EM) radiation. For example, the LC circuit 200 may be tuned to a resonant frequency around 900 MHz, and an antenna in a walk-through alarm gate may be configured to detect an impedance change at the resonant frequency. Under such conditions, detection of backscattered EM radiation by a reader (e.g., in the alarm gate) triggers an alarm. In some embodiments, the resonant circuit 200 may further comprise a second capacitor coupled with the capacitor 220. The second capacitor may be sensitive to a change in resonant frequency (e.g., of the reader/detector and/or the circuit 200).

FIG. 6B shows an exemplary resonant circuit 250 for a wireless device with a sensor 260, suitable for use in the present invention. The resonant circuit 250 also includes the inductor 210, the capacitor 220, and optionally, a memory 270 and a battery 280 that powers the memory 270 and the sensor 260. The sensor 260 may comprise an environmental sensor (e.g., a humidity or temperature sensor), a continuity sensor (e.g., that determines a sealed, open, or damaged state of the package or container to which the tag is attached), a chemical sensor, a product sensor (e.g., that senses or determines one or more properties of the product in the package or container to which the tag is attached), etc., and outputs an electrical signal to the memory 270 corresponding to the condition, state or parameter sensed or detected by the sensor 260. The memory 270 stores one or more bits of data, at least one of which corresponds to the condition, state or parameter sensed or detected by the sensor 260, and one or more of which may correspond to an identification number or code for the product to which the tag is attached. The memory 270 outputs a data signal that can be read by the reader. Thus, the reader is capable of detecting an initial state of the memory 270. Additional circuitry can be added to the circuit 250 to change the state of the memory 270. In addition, such additional circuitry can write data or a state to a ferroelectric capacitor (when present). The resonant circuit may be tuned to an NFC frequency (e.g., 13.56 MHz), but the invention is not limited to this (e.g., the resonant circuit may be tuned to a frequency in the UHF band, the LF band, etc.)

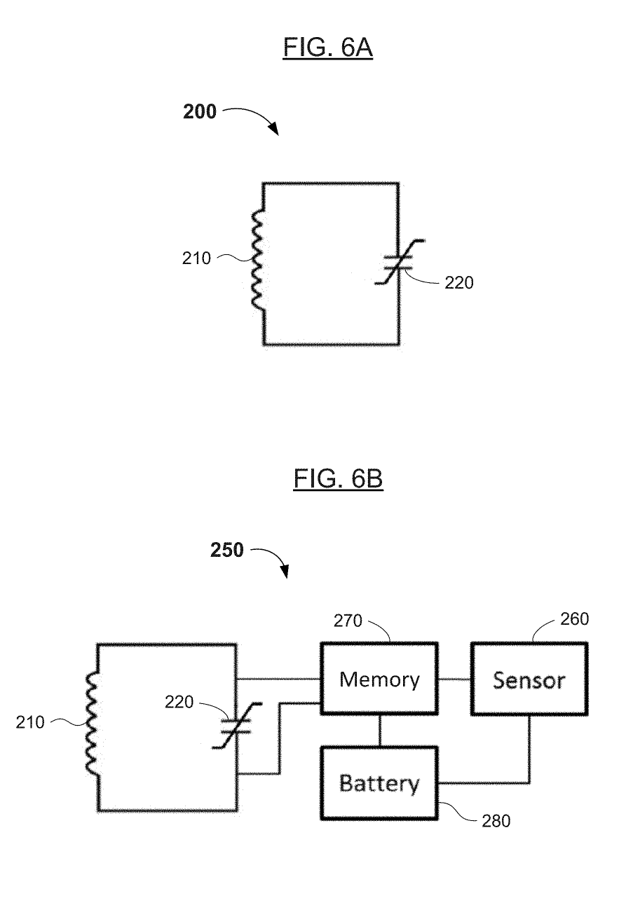

FIG. 7 shows an exemplary integrated circuit 300 that can be made using CMOS devices manufactured in accordance with the present invention. The exemplary integrated circuit (IC) 300 for use with the present “smart label” includes one or more sensors 310, a threshold comparator 320 receiving information (e.g., a signal) from the sensor(s) 310, a pulse driver 340 receiving an output of the threshold comparator 320, a memory 360 storing sensor data from the pulse driver 340, one or more bit lines (BL) 372 for reading data from the memory 360, one or more sense amplifiers (SA) 374 for converting the signal(s) on the bit line(s) to digital signals, one or more latches 376 for temporarily storing data from the sense amplifier(s), and a transmitter (e.g., modulator) 390 configured to output data (including an identification code) from the device. The exemplary IC 300 in FIG. 7 also contains a clock 350 configured to provide a timing signal (e.g., CLK) that controls the timing of certain operations in the IC 300 and a memory timing control block or circuit 370 that controls the timing of memory read operations. The modulator 390 also receives the timing signal (CLK) from the clock circuit or a slowed-down or sped-up variation thereof. The exemplary IC 300 also includes a power supply block or circuit 380 that provides a direct current (e.g., VCC) to various circuits and/or circuit blocks in the IC. The memory 360 may also contain identification code. The portion of the memory 360 containing identification code may be printed. The IC 300 may further contain a receiver (e.g., a demodulator), one or more rectifiers (e.g., a rectifying diode, one or more half-bridge or full-bridge rectifiers, etc.), one or more tuning or storage capacitors, etc. Terminals in the modulator and the power supply are connected to ends of the antenna (e.g., at Coil1 and Coil2).

The memory in an NFC or RF identification device (which can be implemented using the IC 300) may contain a fixed number of bits. In some implementations, NFC tags may contain 128 or 256 bits. Some bits are allocated to overhead (non-payload) data for format identification and data integrity (CRC) checking. The payload of the device (e.g., the NFC or RF tag) consumes the remainder of the bits. For example, the payload can be up to 96 bits in the case of the 128-bit NFC tag and up to 224 bits in the case of the 256-bit NFC tag.

The payload of the NFC tag can be allocated to variable amounts of fixed ROM bits (which are generally—but not always—used as a unique identification number). When print methods are used in manufacturing the NFC tag, the ROM bits are permanently encoded and cannot be electrically modified. Any payload bits that are not allocated as fixed ROM bits can be allocated as dynamic sensor bits (e.g., for storing a state from the sensor 310, such as a continuity state, temperature level [e.g., above or below a threshold temperature], humidity level [e.g., above or below a threshold relative humidity value], etc.). These sensor bits can change values, based on a sensed input. The ROM ID bits do not change, but any data integrity bits (e.g., CRC bits) may be updated to reflect the state of the sensor bits. Different splits or allocations between ROM and sensor bits are indicated by data format bits that are part of the non-payload or “overhead” bits, generally in the first 16 bits of the NFC tag memory.

The IC 300 in the present device may include a plurality of sensors 310. For example, the IC 300 can further include one or more temperature sensors, humidity sensors, electromagnetic field sensors, current/voltage/power sensors, light sensors, and/or chemical sensors (e.g., for oxygen, carbon monoxide, carbon dioxide, nitrogen oxides, sulfur dioxide and/or trioxide, ozone, one or more toxins, etc.) in addition to one or more continuity sensor(s). The present IC may also include one or more time sensors (e.g., configured to count or determine elapsed time), which may include the clock circuit 350 (which can be a basis for a real-time clock) and one or more counters, dividers, etc., as is known in the art. The leads from any external sensing mechanism should be connected to the IC at terminals separate from those for the antenna and the continuity sensor. Such sensors should be on the same part of the substrate as the antenna and the IC.

Exemplary Methods of Making CMOS Devices

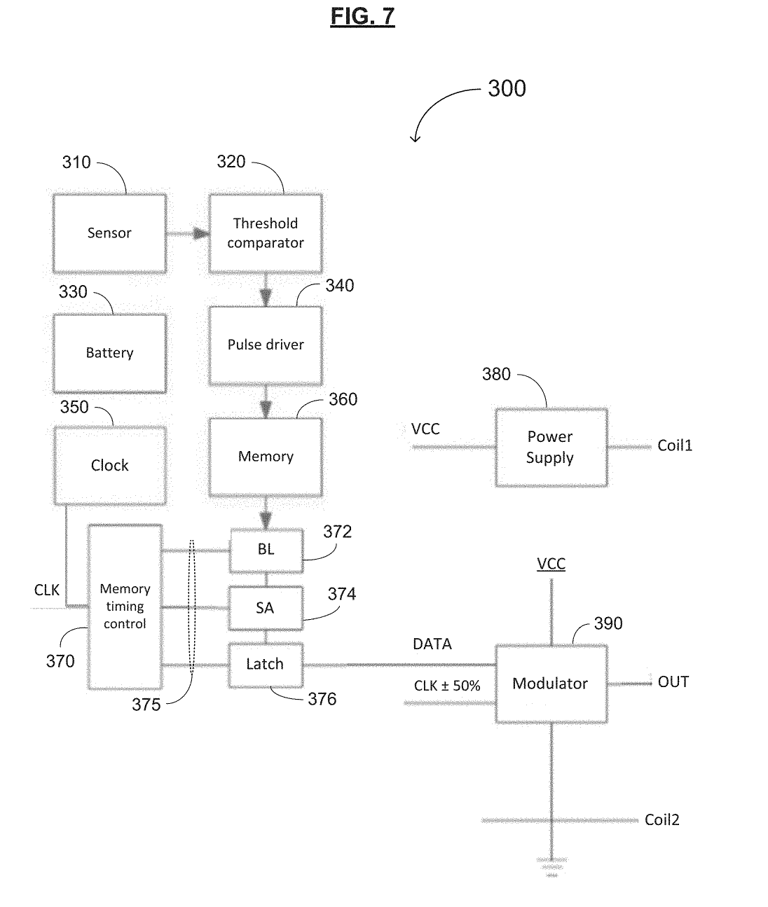

FIGS. 8A-B are flow charts 400 and 500, respectively, for exemplary methods of making CMOS devices in accordance with embodiments of the present invention.

In FIG. 8A, at 410, a gate oxide layer is formed on an exposed active layer of a semiconductor device, as described herein. The exposed active semiconductor layer may comprise a blanket-deposited or printed semiconductor material, such as an inorganic semiconductor (e.g., a Group 4 semiconductor such as Si and/or Ge, a III-V semiconductor such as GaAs and/or InP, a II-VI semiconductor such as ZnO or ZnS, etc.) or an organic semiconductor (e.g., a polythiophene, polyphenylenevinylene, polynaphthalenevinylene, polyacetylene, or polyfluorene semiconductor; a poly(carbazole-dithiophene-benzothiadiazole) copolymer; etc.). The printed semiconductor material may be in the form of a plurality of physically isolated semiconductor islands, each of which may form the exposed active layer for one or more NMOS or PMOS devices. The active semiconductor layer may be on a substrate, as described herein.

At 420, gates are formed on the gate oxide layer(s), as described herein. At 430, spacers may be formed on the gate oxide layer(s), adjacent to the gates. After formation of the gates and the spacers, the exposed gate oxide layer(s) may be etched as described herein (e.g., using the gates and the spacers as a mask).

Thereafter, the method may form a thin AlN layer on the gates, the exposed active semiconductor layer(s), and the spacers at 440, and optionally, a thin silicon oxide layer on the AlN layer, as described herein. The AlN layer is generally blanket-deposited to a thickness of about 20-100 Å, and the silicon oxide layer is generally blanket-deposited to a thickness of about 10-100 Å. In one embodiment, the thin silicon oxide layer may be removed from regions of the active semiconductor layer or the substrate corresponding to NMOS devices.

Thereafter, at 450, a single dopant type ink is printed onto the AlN (or, if present, the silicon oxide layer). In one embodiment, a dopant ink for PMOS devices is printed onto the AlN layer (or the silicon oxide layer). Alternatively, an ink for NMOS devices may be printed onto the AlN layer (or the silicon oxide layer).

The dopant(s) from the single dopant type ink are diffused through the silicon oxide layer (if present) and the AlN layer into the active semiconductor layer at 460, generally after drying the ink(s) to form a dopant layer, as described herein. After the dopant(s) are diffused into the active semiconductor layer, the dopant(s) are activated as described herein.

At 470, a surface cleaning step may be performed as described herein. Optionally, if an oxide layer (formed at 440) is present, the oxide layer may be removed at 472, as described herein. The AlN layer can also be optionally removed at 472 as well, as described herein. Optionally, at 474, a new AlN layer may be formed over the gates and spacers, if the AlN layer was removed at 472. The new thin AlN layer may be formed in the same manner and have the same characteristics as the AlN layer formed at 440. The AlN may comprise a compound of the formula AlₓSi_{y}O_{z}Nₚ, as described herein.

At 480, a second, complementary dopant type ink (e.g., an NMOS ink) is printed. The second dopant type ink is printed as described herein onto the AlN layer (old or new) in regions corresponding to devices of the complementary dopant type. For example, an ink for NMOS devices is printed at 480 if an ink for PMOS devices was printed earlier. Alternatively, if an NMOS ink was printed earlier, a PMOS ink is printed onto the AlN layer at 480 in regions corresponding to PMOS devices, as described herein. The dopant ink printed at 480 is dried as described herein.

Alternatively, the PMOS and NMOS inks may be printed sequentially (in either order) at 450. In one embodiment in which the silicon oxide layer is formed, the PMOS ink may be printed onto the silicon oxide layer, and the silicon oxide layer may be removed from regions corresponding to NMOS devices, and the NMOS ink may be printed onto the AlN layer.

At 490, the dopant from the NMOS ink (or the PMOS ink, if printed at 480) is diffused through the AlN layer (and the silicon oxide layer, if present) into the active semiconductor layer, as described herein. After the dopant is diffused into the active semiconductor layer, the dopant is activated as described herein. A surface cleaning step is performed at 495, as described herein. The AlN layer (new, or if present, old) may also be removed at 495, or if desired, kept over the NMOS and PMOS devices. In the latter case the AlN layer may function as an etch stop layer for etching any subsequently deposited dielectric material (e.g., a silicon oxide-based interlayer dielectric).

After 495, the method may end. However, further embodiments of the method may comprise depositing an interlayer dielectric onto the NMOS and PMOS devices (on which the AlN layer may remain), forming contact holes in the interlayer dielectric as described herein to expose contact areas of the active semiconductor layer, optionally forming ohmic contact layers on the exposed areas of the active semiconductor layer, and/or forming a metallization and/or interconnect layer on the interlayer dielectric (and optionally in the contact holes in the interlayer dielectric).

FIG. 8B outlines an alternate method 500, in which a relatively thin gate oxide layer (e.g., having a thickness of 20-200 Å) may be formed, and the spacer is eliminated. The process flow as described in FIG. 8B may be useful for making the structures shown in FIGS. 2F-I.

At 510, the gate oxide is formed on the active layers (similar to 410 in FIG. 8A). A gate layer is formed (e.g., by blanket deposition) on the gate oxide layer at 520 (similar to 420 in FIG. 8A). The gate layer is then etched (wet or dry) at 530 to form the gates. At 540, a thin AlN layer is formed over the gates, without forming spacers. Optionally, an additional oxide layer may be formed at 545. The layer may be a bilayer as described herein.

A single type dopant is then printed over the AlN and gate layer at 550. The gate oxide layer is kept intact (e.g., not etched). The dopant ink is diffused into the silicon layer and activated, thereby forming the source and drain regions at 560. A surface cleaning step is performed at 570. Optionally, the AlN layer is removed at 570, or it may otherwise be kept intact for later processing.

Experimental Results

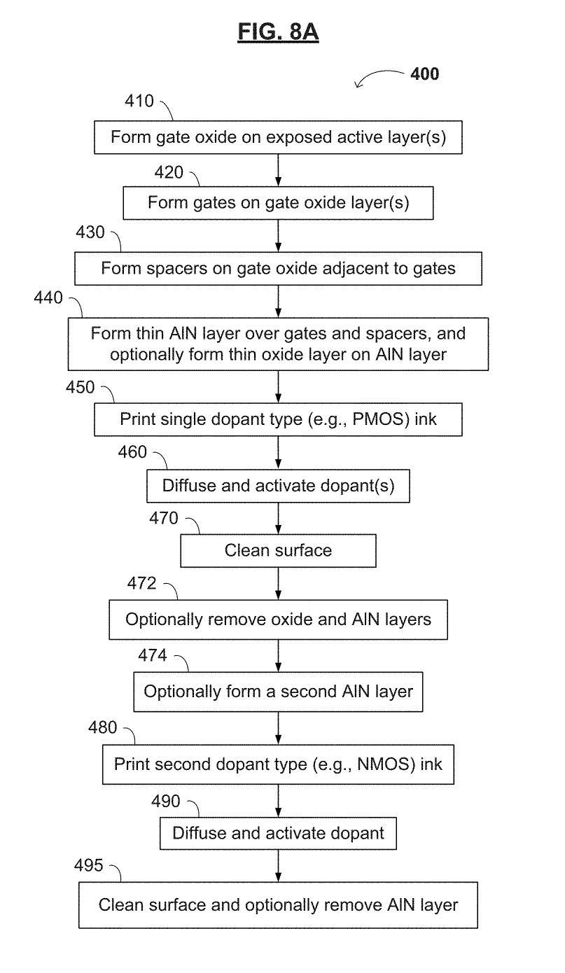

FIG. 9 is a graph showing the breakdown voltage of a 35 Å-thick gate oxide of NMOS devices having a 1000 Å-thick tungsten gate, over a recrystallized, doped silicon layer on a stainless steel foil coated with a barrier layer and a silicon dioxide pad layer (under the doped silicon layer), configured as capacitors. The devices were made by the method outlined in FIG. 8B. The NMOS devices further included either (i) a 35 Å-thick AlN layer on the gate and the gate oxide layer or (ii) a sidewall spacer on the gate oxide layer, formed prior to the dopant layer. The first column from the left shows samples from three (3) regions of the stainless steel substrate, where the dopant layer was formed from a printed ink containing a phosphorous source, such as phosphoric acid. The second column from the left shows samples from three (3) different regions of the same stainless steel substrate, where the dopant layer was formed from a printed ink containing a different amount of the phosphorous source. The gate oxide thickness was 35 Å in each of these six (6) regions. The third column from the left shows samples from two (2) regions of the stainless steel substrate, where the NMOS devices further included a silicon dioxide sidewall spacer, the dopant layer was formed from a printed ink having the same nominal composition as that forming the dopant layer in the samples of the first column, and the gate oxide thickness was 35 Å. The fourth column from the left shows samples from one (1) remaining region of the stainless steel substrate, where the NMOS devices further included the silicon dioxide sidewall spacer, the dopant layer was formed from the same printed ink, and the gate oxide thickness was 35 Å.

A number of open circuits (which are plotted outside of the range 0-10V) resulted from the spacer process in each region of the third column in FIG. 9, and one open circuit resulted from the spacer process in the single region of the fourth column. By contrast, only one open circuit resulted from the AlN process in the three (3) regions in each of the two (2) AlN processes in FIG. 9. In addition, the distribution of breakdown voltages in the NMOS capacitors in each of the six (6) regions manufactured by the AlN processes was significantly smaller (and thus more uniform) than the breakdown voltages in the NMOS capacitors in each of the three (3) regions manufactured by the spacer processes.

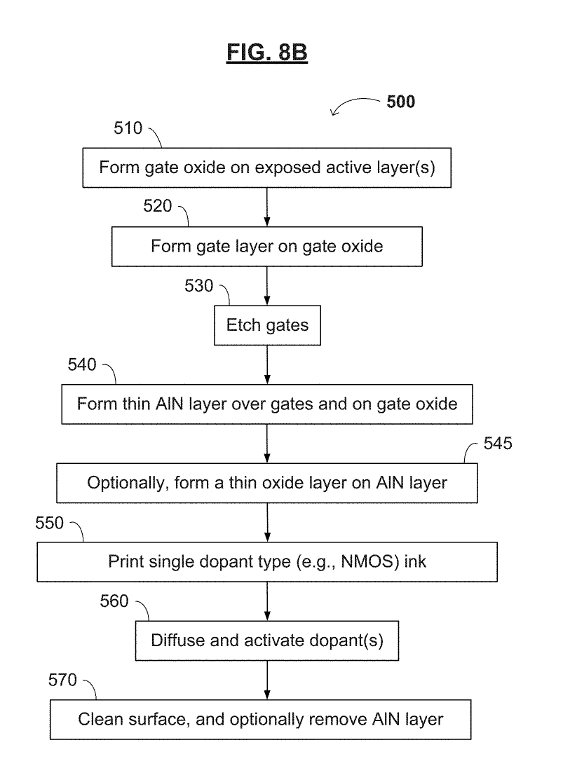

FIG. 10 is a graph showing the sheet resistance of a silicon layer doped in accordance with an embodiment of the present method. The samples all included a stainless steel substrate with a diffusion barrier layer thereon, a pad oxide layer on the diffusion barrier layer, a recrystallized silicon layer on the pad oxide layer, an unpatterned gate oxide with a thickness of 350 Å on the silicon layer, and an aluminum nitride layer on the gate oxide. The diffusion barrier layer had a thickness of 1200 Å. The silicon layer was formed by spin-coating, drying and curing an ink containing a polysilane to form an amorphous silicon film, then laser-crystallizing the amorphous silicon film. The silicon layer had a thickness of approximately 650 Å. A dopant layer was formed on the aluminum nitride layer by printing a dopant ink with a phosphorous containing compound as the dopant source. The first two (2) columns from the left, in which the samples were annealed at 650° C. for 12 hours, show sheet resistances generally in the range of from a little under 400 Ω/cm² to about 550 Ω/cm². The middle two (2) columns of data, in which the samples were annealed at 700° C. for 2 hours, show sheet resistances generally in the range of from about 600 Ω/cm² or a little under to 900-1150 Ω/cm². The two (2) right columns of data, in which the samples were annealed at 730 ° C. for 2 hours, show sheet resistances generally in the range of from about 300 or 350 Ω/cm² to about 400 Ω/cm² or a little under. In each group of two columns, the left-hand column is for samples having a 35 Å-thick aluminum nitride layer, and the right-hand column is for samples having a 50 Å-thick aluminum nitride layer.

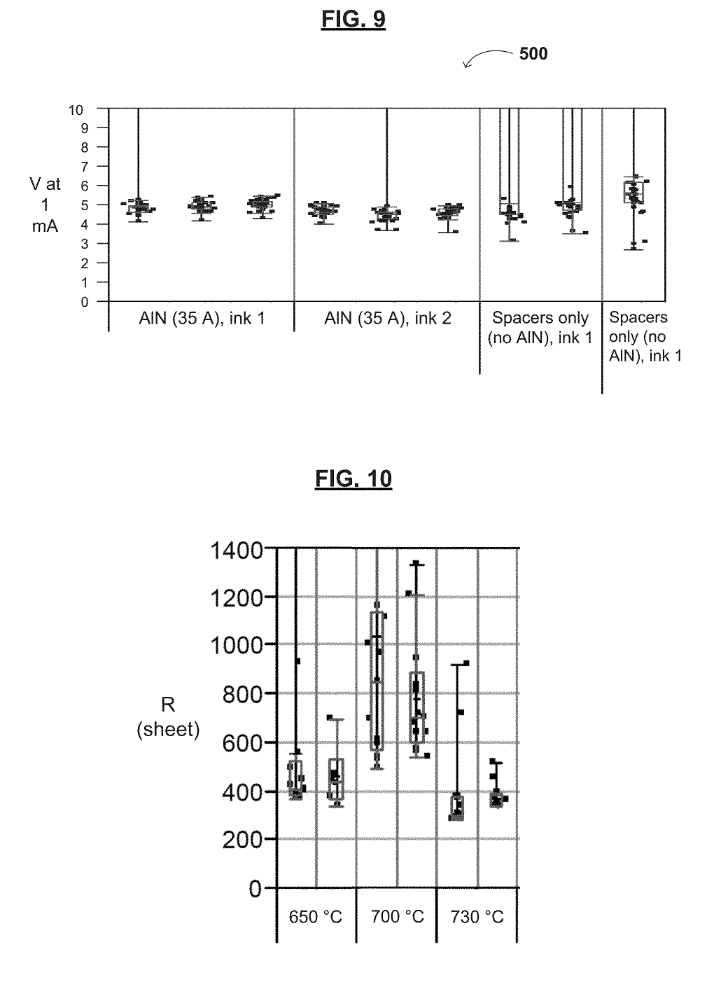

FIG. 11 is a graph showing the sheet resistance of a silicon layer doped in accordance with embodiments of the present method. The samples in each of the columns of FIG. 11 were the same as for FIG. 9. All activations were performed at 790° C. A reduction of about 10-fold in active sheet resistance (R) is achieved by using an AlN layer instead of spacers and an oxide layer (or an oxide layer alone) at the same dopant concentration (e.g., compare the left-most column with the two right-most columns). Further reductions and improvements in uniformity are achieved with the use of a dopant ink containing a higher concentration of the dopant source (e.g., the sheet resistance was <200 Ohms/sq when the samples included an AlN layer with a thickness of 35 Å and a dopant layer with a higher concentration of the dopant source).

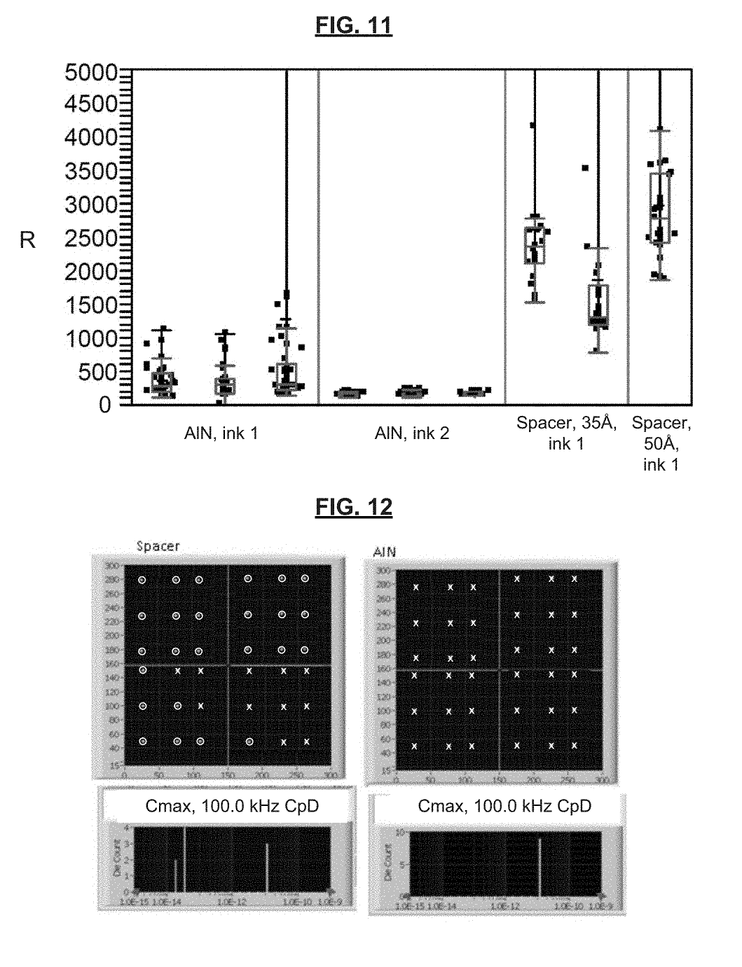

FIG. 12 shows two plots of capacitances of NMOS devices on a 300 mm stainless steel sheet having a diffusion barrier layer and a silicon dioxide insulator layer thereon. The NMOS devices were made in a manner similar to those described with respect to FIG. 9 (half of the devices were made with a 35 Å-thick AlN layer on the gate and the gate oxide layer, and the other half with a sidewall spacer on the gate oxide layer). In all of the devices, the AlN layer or the sidewall spacer was formed prior to formation of a dopant layer from a printed ink containing phosphoric acid as the dopant. Each device on the stainless steel sheet was identically wired as a capacitor. The gate oxide thickness was the same for all of the devices on the stainless steel sheet. The capacitance of the devices across the 300 mm sheet is shown in the bottom plots. In the upper plots, a circle indicates an electrical open or electrical short (i.e., a non-functional device) due to overetching during the spacer etch step. An “x” indicates a functional device. The yield of the devices made using the AlN layer was 100%, whereas the yield of the devices made using the sidewall spacer was about 30%. The capacitances of the functional devices made using either process was the same (about 2.5-3 pF), confirming that the processes were identical other than the presence or absence of the AlN layer and the sidewall spacer.

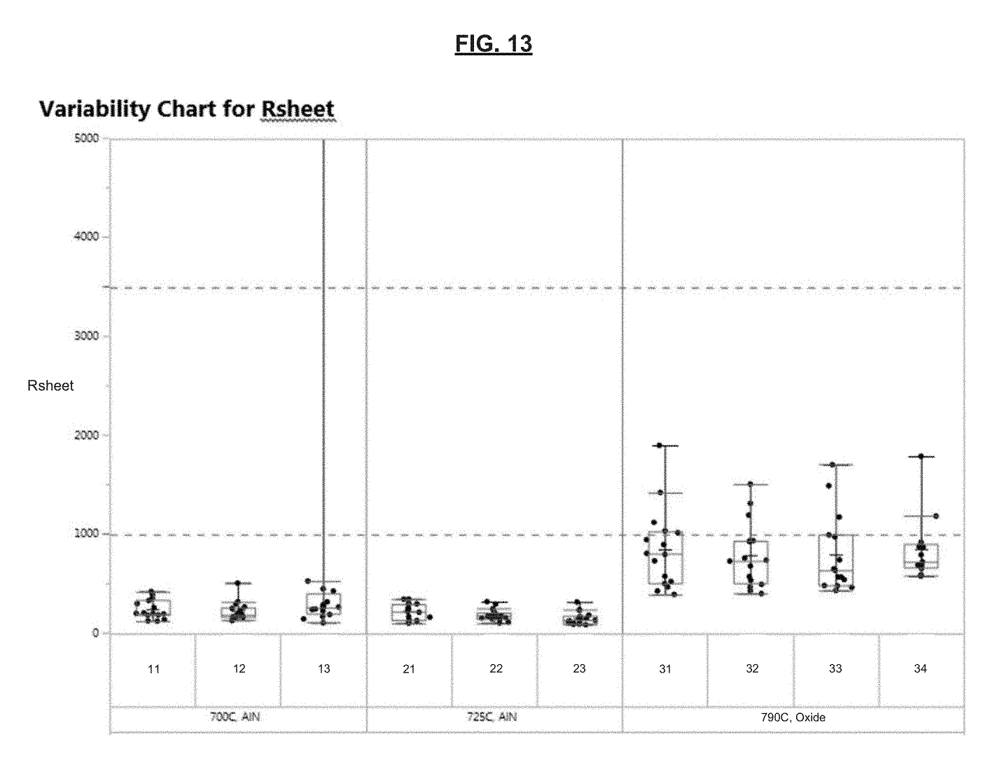

FIG. 13 is a variability chart showing the sheet resistance of a silicon layer doped in accordance with another embodiment of the present method. Samples 11-13 included a layer of AlN having a thickness of 50 Å, and were annealed at 700° C. for 2 hours. Samples 21-23 were the same as Samples 11-13 (including the layer of AlN), but were annealed at 725° C. for 2 hours. Samples 31-34 were substantially identical to Samples 11-13, except that a layer of SiO₂ having a thickness of 35 Å replaced the AlN layer, and Samples 31-34 were annealed at 790° C. for 2 hours. Samples 11-13 show sheet resistances generally in the range of from about 100 Ω/cm² to about 500 Ω/cm². Samples 21-23 show sheet resistances generally in the range of from about 100 Ω/cm² or a little less to about 400 Ω/cm². By contrast, Samples 31-34 show sheet resistances generally in the range of from about 400 Ω/cm² or a little more to about 1800 Ω/cm² or more. Thus, not only is the annealing temperature reduced when using an AlN cap layer instead of an oxide cap layer, but the average sheet resistance is significantly lower (e.g., by about half), and the absolute range or variability of the sheet resistance is greatly reduced.

### CONCLUSIONS

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

What is claimed is:

A method of making a MOS device, comprising:
a) depositing an aluminum nitride layer on a structure comprising a silicon layer, a gate oxide layer on the silicon layer, and a gate on the gate oxide layer;
b) depositing a dopant ink on the structure, the dopant ink comprising a dopant and a solvent; and
c) diffusing the dopant through the aluminum nitride layer into the silicon layer.

2. The method of claim 1, further comprising making said structure by a process that comprises forming the gate oxide layer on the silicon layer, and forming the gate on the gate oxide layer.

3. The method of claim 2, wherein making said structure further comprises forming a sidewall spacer on side surfaces of the gate.

4. The method of claim 2, wherein making said structure further comprises forming the silicon layer on a substrate.

5. The method of claim 4, wherein forming the silicon layer comprises depositing a silicon-containing ink on the substrate, and the silicon-containing ink comprises a silane and a solvent in which the silane is soluble.

6. The method of claim 11, wherein the substrate comprises a sheet or foil of a metal, or a sheet, disc, wafer or film of a ceramic, a glass, or a polymer.

7. The method of claim 1, wherein the dopant ink comprises a dopant source, the solvent, and an acrylic or methacrylic polymer.

8. The method of claim 1, further comprising activating the dopant after diffusing the dopant into the silicon layer.

9. The method of claim 8, wherein the dopant is activated at a temperature of 600-740° C.

10. The method of claim 8, wherein the dopant is activated at a temperature of at least 50° C. below a minimum activation temperature of an identical device having a silicon oxide layer in place of the aluminum nitride layer under otherwise identical activation conditions, the silicon oxide layer having a thickness identical to that of the aluminum nitride layer.

11. The method of claim 1, wherein the aluminum nitride layer has a thickness of from 20-200 Å.

12. The method of claim 1, further comprising depositing a silicon dioxide layer on the aluminum nitride layer, wherein the method comprises depositing the dopant ink onto the silicon dioxide layer, and the dopant ink comprises a compound and/or precursor of boron or gallium.

13. The method of claim 12, wherein the method comprises making a plurality of PMOS devices and a plurality of NMOS devices, depositing the dopant ink comprises printing a PMOS ink comprising (i) the compound and/or precursor of boron or gallium and (ii) a first solvent on the silicon oxide layer over structures corresponding to said PMOS devices, and the method further comprises:
removing the silicon oxide layer after diffusing the boron or gallium dopant through the aluminum nitride layer into the silicon layer corresponding to said PMOS devices;
printing an NMOS ink comprising (i) a compound and/or precursor of antimony, arsenic, or phosphorous and (ii) a second solvent onto the aluminum nitride layer over structures corresponding to said NMOS devices; and
diffusing the antimony, arsenic, or phosphorous dopant through the aluminum nitride layer into the silicon layer corresponding to said NMOS devices.

14. The method of claim 1, wherein the method further comprises removing the aluminum nitride layer after diffusing the dopant into the silicon layer.

15. A MOS device, comprising:
a) a silicon layer,
b) a gate oxide layer on the silicon layer,
c) a gate on the gate oxide layer; and
d) an aluminum nitride layer on the gate,
wherein the silicon layer includes a dopant on opposite sides of the gate.

16. The device of claim 15, further comprising forming a sidewall spacer on side surfaces of the gate and an upper surface of the gate oxide layer.

17. The device of claim 15, wherein the silicon layer comprises a photolithographically-patterned or printed silicon island.

18. The device of claim 15, further comprising a substrate supporting the silicon layer, wherein the substrate comprises a sheet or foil of a metal, or a sheet, disc, wafer or film of a ceramic, a glass, or a polymer.

19. The device of claim 15, wherein the aluminum nitride layer has a thickness of from 20-200 Å.

20. A CMOS circuit, comprising a plurality of the NMOS devices of claim 15 and a plurality of PMOS devices, wherein each of the PMOS devices comprises:
a) a separate silicon layer,
b) a separate gate oxide layer on the separate silicon layer,
c) a separate gate on the separate gate oxide layer; and
d) the aluminum nitride layer on the separate gate,
wherein the separate silicon layer includes a boron or gallium dopant on opposite sides of the separate gate.
